(19) United States
(12) Patent Application Publication
(10) Pub. No.: US 2003/0232287 A1
(43) Pub. Date: Dec. 18, 2003

(54) Method for stromal corneal repair and refractive alteration using photolithography

(76) Inventor: Joseph J. Bango, New Haven, CT (US)

Correspondence Address: CONN. ANALYTICAL CORP., Att: Joseph J. Bango, Jr., 696 AMITY ROAD, BETHANY, CT, 06524, US

(21) Appl. No.: 10/461,267

(22) Filed: Jun. 14, 2003

Related U.S. Application Data
(60) Provisional application No. 60/388,964, filed on Jun. 14, 2002.

(51) Int. Cl. G03F 7/20; G03F 7/26; G03F 7/42

(52) U.S. Cl. 430/321; 430/322; 430/329

(57) ABSTRACT

A method and means of providing stromal repair and improved refractive correction. The invention discloses a technique for creating corneal stromal collagen tissue with fibril diameter and spacing that duplicates the optical transmission and diffusion characteristics of natural corneal collagen. Repair method includes implanting the collagen scaffold during LASIK or other inter-lamellar surgery to improve visual acuity or to preclude the possibility of ectasia.

### REFERENCE

Provisional Application No. 60/388,964, Filed Jun. 14, 2002

### BACKGROUND OF THE INVENTION

This invention relates in general to corneal reconstruction and in particular to a method and means of regenerating a corneal lamella membrane in an effort to restore vision in-patients suffering from failed LASIK, radial keratomy, keratoconus, corneal abrasions, and trauma. Further, this invention holds promise as a method to devise a living ‘contact lens’, implanting tissue into the corneal stroma.

1. Field

This invention relates in general to corneal reconstruction and in particular to a method and means of regenerating a corneal lamella membrane in an effort to restore vision in patients suffering from failed Laser Corneal Ablation Procedure (LCAP) such as those described as LASIK or LASEK, radial keratomy, keratoconus, corneal abrasions, and trauma. Further, this invention holds promise as a method to devise a integral refractive correcting contact-like lens which can be implanted on top of or into the corneal stroma.

2. Prior Art

Corneal damage is a leading cause of impaired vision and blindness. Scarring due to chemical burns, missile damage, genetic disorders, radial keratomy, or failed LCAP are leading causes of corneal eye damage. In particular, failed LCAP is the most common source of vision loss due to corneal damage. Refractive complications can include too much or too little correction, or an imbalance in correction between the eyes. In some cases, patients who experience improper LCAP may be left near or farsighted or with astigmatism, necessitating spectacles or contact lens wear, or in severe cases, may be faced with blindness. Corneal inflammation is another side effect, which can cause a swelling known as diffuse interface keratitis, leading to corneal hazing, and ultimately, blurred vision. LCAP performed on certain patients with large pupil diameters, thin corneas, or keratoconus, leading to night glare, starbursting, haloes, reduced vision under dim lighting, blurring, or reduced overall visual acuity. At present, only corneal transplants or penetrating keratoplasty, are considered a viable treatment.

Given the enormous media attention given to LCAP, most individuals readily embrace LCAP as a cure-all solution to disposing of their glasses and contact lenses. However, all ophthalmologists readily admit, in their FDA-mandated informed consent that not everyone sees well enough after a LCAP procedure to truly eliminate their use of glasses and contact lenses. In fact, studies have shown that over 2 percent of LCAP patients experience degradation in visual acuity that was uncorrectable through refractive means. Of these patients, debilitating effects due to irregular astigmatism and double vision (due to corneal warping) were common. This is particularly troublesome since, unlike cataract surgery, which restores vision in defective eyes, LCAP is an elective process practiced on healthy eyes. While LCAP is certainly a preferable procedure over radial keratotomy, the success of the procedure and the coupling of medicine and marketing has caused in many patients, who should not have undergone the process to be largely forgotten. Further, intraoperative complications include decentered ablations and flap complications, such as a partial or lost flap.

Postoperative effects due to failed LCAP can include pain as a result of disturbance of the epithelial layer, displacement of the corneal flap, inflammation, or infection. Diffuse interface or lamellar keratitis, also known as ‘DLK’ or Sands of Sahara, is the most serious reaction and can produce corneal hazing, blurred vision, farsightedness, astigmatism, and permanent corneal irregularities. Another equally serious complication is keratoectasia induced by LCAP. Ectasia is the distension of the cornea due to an internal pressure gradient causing the cornea to steepen and distort. The most common side effects of LCAP are dryness of the eyes, night glare, starbursting, haloes, induced spherical aberration, induced coma, and reduced visual acuity. Previous attempts to correct the corneal structure to alleviate the aforementioned conditions have been hampered by the fact that only a fixed quantity of tissue is available for ablative modification. By its' very nature, laser ablation or LCAP removes healthy tissue, thus undermining the structural integrity of the cornea. Replacement tissue is not available due to the fact that no other part of the body has the specialized collagen fibril structure inherent in the cornea.

The most widely practiced means of corneal repair has been the corneal transplant. However, problems of tissue rejection, of immunosuppressive medication, gross refractive errors, and limited supplies of suitable donor tissue hamper transplants. While numerous experiments have been conducted in an effort to create laboratory-grown corneal tissue in vitro, the drawback of most of these methods is that they attempt to generate only one type of corneal cell structure, such as the epithelial or endothelial layers. Stromal creation in the laboratory has in the past been met with limited success since no means have been found that successfully form the delicate collagen fibrils with micron sized diameters and fibril spacing necessary for corneal transparency and diffusive permeability.

Many prior art techniques rely on implanting a polymer of material (other than collagen or collagen that is devoid of fibrils), thus lacking in permeability as well as transparency inherent in native tissue. For example, U.S. Pat. No. 4,505,855 to Bruns and Gross issued Mar. 19, 1985, describes the fabrication of a non-fibrilized collagen button produced by ultracentrifugation for transplantation. This concept suffers from the fact that the lack of a controlled fibril diameter and fibril organizational structure significantly hinders the osmotic pumping of proteins and aqueous media through the fabricated collagen region. The same holds true with gaseous diffusion. As a result, transparency will be impaired. Further, since the collagen button is designed to replace only the damaged corneal stroma, leaving out other vital tissues (the stroma is responsible for 90% of corneal thickness, composed of collagen fibrils and is the principal supportive structure of the cornea. Covering the stroma is the epithelium, a cellular membrane about 5 layers thick, below which is the Bowman's Layer, a thin layer separating epithelium and stroma. On the anterior portion of the stroma is the endothelium layer, responsible for dehydrating the cornea via a sodium-potassium pump mechanism and to maintain corneal optical clarity. Last is the Descemet's membrane, which is the endothelium basement membrane. All these layers are all conspicuously absent in Bruns et al. Also, since the source of collagen is not exclusively from the patient or a sterile genetically engineered source, the possibility of a gross immunologic reaction is significant.

Published U.S. patent application No. 88,307,687 to Werblin and Patel, describes a lens produced from a hydrogel material that is inserted under a corneal cap. As indicated in U.S. Pat. No. 4,505,855 to Bruns et al, dated Mar. 19, 1985, any material that is not identical to native tissue can and will affect optical clarity and diffusive capacity required for a healthy corneal structure.

Again, any means of producing a polymer implant which reduces the diffusion rate of oxygen, lipids, or aqueous media, reduces the effectiveness of the implant. Subtle changes in the intraocular pumping mechanism can cause significant loss in visual acuity. As before, nonnatural polymers can be rejected by the immune system.

Similar implants are revealed in prior art such as that described in European Patent No. 443,094/EP B1 to Kelman & DeVore. They utilize polymerized collagen material in conjunction with a periphery of fibrilized collagen. While providing improvements over simple collagen or other polymer implants, this suffers from the fact that the polymerized collagenous core does not contain fibrils at all as native tissue. Moreover, the fibrils on the periphery are not of the same diameter as in native tissue. As such, the permeability of the implant is low, thus affecting corneal hydration and overall nutritional levels. Further, since the collagen source employed can be derived from nonhuman sources, there is a susceptibility to immunologic effects.

European Patent No. 339,080/EP A1 to Gibson, Lerner, et al., reveals an improved prosthetic corneal implant in that the surface of the polymer is coated with crosslinked or uncrosslinked fibronectin. While this coating does improve epithelial adhesion, the problems of lack of diffusibility, optical clarity, and foreign body rejection are still present.

It is known to inject specialized gels in an effort to improve or change the radius of curvature of the cornea. U.S. Pat. No. 5,681,869 to Villain, et al., describes a biocompatable polyethylene oxide gel for injection into the cornea as a method of tissue augmentation. This procedure suffers from the fact that any gel lacks inherent structural integrity and thus can only augment existing tissue through limited hydrodynamic forces. Optical transmissibility and permeability are limited relative to material produced by the disclosed invention. Foreign body rejection is also possible.

Several prior art references disclose means of corneal repair through application of a suitable topographical ointment or solution. European Patent No. 778,021/EP A1 and Japanese Patent No. 8,133,968 JP to Ohuchi and Kato, disclose a solution of eye drops comprised of water, sodium chloride, potassium chloride, sodium bicarbonate, and taurine. This product suffers from the fact that as essentially a simple buffered isotonic saline solution, it is incapable of rendering any of the structural changes in the cornea required to correct high astigmatism, keratoconus, ectasia, burns, or corneal thinning. Further, the solution of Ohuchi and Kato is capable only of yielding temporary corneal surface relief due to minor, transient optical modifications.

European Patent Publication Nos. WO 00218441 and WO 00240242 to Bowlin & Wnek etal., published Mar. 7, 2002 and April 8^{th} respectively, describe electrospun collagen fibers used a tissue scaffolds. Further, claims are made that the geometry of the electroprocessed matrix can be controlled by microprocessor regulation or by moving the spray nozzle with respect to the target or vice versa. In reality, the electric charge that builds up on an electrospun fiber is significant, and results in whipping effect, which can vary fiber diameter and make precise deposition impossible as the fiber splays about the target. This is because the DC high voltage source used in Bowlin et al., allows a like charge to accumulate on the fiber. As the fiber is ejected, a radius in the fiber will result in like charge repulsive forces to deflect the fiber in the opposite direction, where the radius decreases and the repulsive force increases. This process repeats itself, leading an uncontrolled ability to deposit material at a precise target and pattern. Further, the splaying about of the fibers results in tensile forces which varies the fiber diameter considerably.

The principal goal of the cited invention is to fabricate collagen constructs which serve as cell growth scaffold and to encourage neovascularization or blood vessel in growth. However, cell and vessel in growth are detrimental to a successful corneal collagen fibril structure and if allowed to transpire, would result in blindness. Finally, the precise fibril diameter and mean spacing between such fibrils in that construct necessary for corneal use is not described in Bowlin et al. And the lack of such exact fibril specification, uniform diameter, and matrix pattern would result in reduced optical transparency of the material and insufficient permeability for ocular use.

### OBJECTS AND ADVANTAGES

The disclosed invention overcomes many of the limitations inherent in corneal transplants, solid polymer implants, mechanical implants employed to distort or reinforce the cornea, and much more, including the following:

(a) It provides a means of producing collagen polymer scaffolds in organized fibers at the same diameter and spacing as natural corneal stromal collagen, assuring the same optical clarity and diffusion characteristics as the original tissue. Significantly, this process permits additional tissue to be added to the cornea to augment structural integrity, therein correcting astigmatism, ectasia, failed LCAP, keratoconus, and other corneal problems.

(b) It affords a means of arranging an organized collagen fibril matrix which accurately mimics natural corneal stromal collagen.

(c) It teaches a means to affix the specialized collagen polymer matrix to the surrounding stromal tissue using glycerose, thereby precluding corneal cap displacement and enhancing the structural integrity of the stroma.

(d) It yields a means of producing a viable collagen polymer refractive correcting lens whose characteristics duplicate natural tissue and is capable of being integrated into and compatible with, the surrounding corneal collagen. This tissue is refractive and is ablatable for LCAP optimization.

(e) It teaches a means to create corneal collagen matrix of the diameter, spacing, and pattern that mimics native tissue, necessary for proper transparency and hydration of the cornea.

Further objects and advantages will become apparent from a consideration of the ensuing description and accompanying drawings.

Reference Numerals in the Drawings

| | |
|---|---|
| 10 Light Source | 20 MaskLayer |
| 30 Collagen Film or Wafer | 40 Photo Resist |
| 50 Positive Etched Pattern | 60 Negative Etched Pattern |
| 70 Contact Exposure | 80 Proximity Exposure |
| 90 Projection Exposure | 100 Gap |
| 110 Primary Optical System | 120 Secondary Optical System |

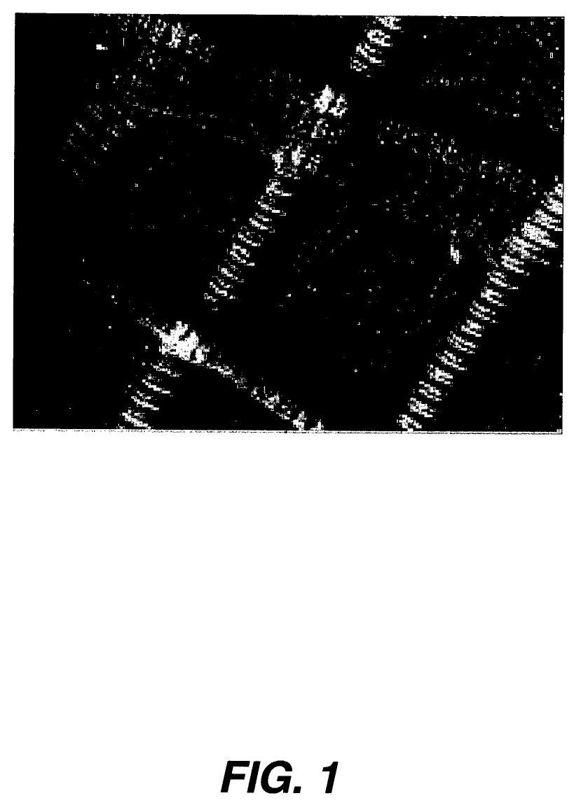

### DESCRIPTION—FIGS. 1 to 4

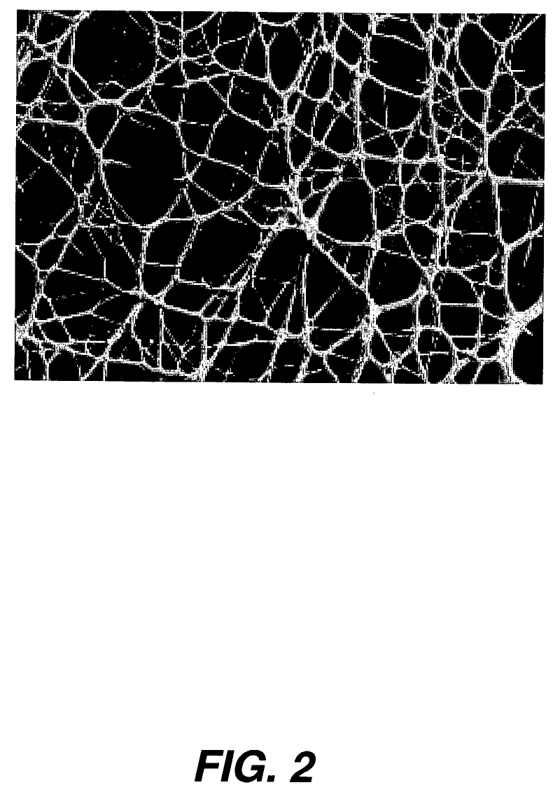

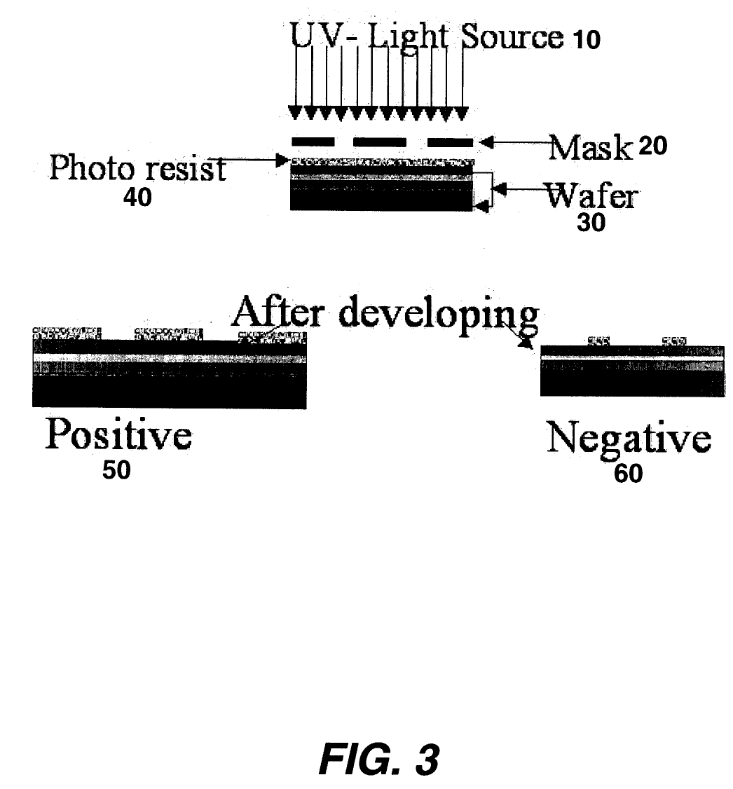

FIG. 1 illustrates the detail of human corneal stromal collagen fibrils obtained by scanning electron microscopy. Typical random collagen deposition pattern obtained using standard electrospinning practice in FIG. 2. The photolithography process employed to create specific collagen micro structures is shown in FIG. 3. The light source 10, preferably ultraviolet, is situated above the mask 20. The collagen thin film or sheet or wafer 30 is coated with a suitable photo resist 40. After a suitable exposure, developing and subsequent rinsing, a positive 50 or a negative 60 collagen pattern is produced.

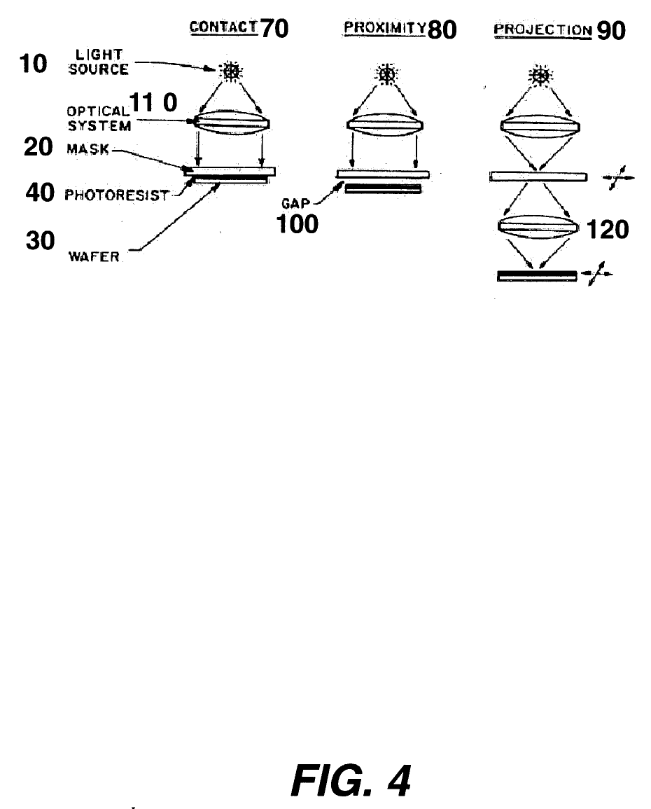

FIG. 4 shows the different methods of exposure. The light source 10 is located above the primary optical system 110. Contact exposure 70 requires that the collagen film or wafer 30 with photo resist 40 is in direct contact with the mask 20 surface. Proximity exposure permits a small gap 100 between the film or wafer and the mask 20. In projection exposure, the mask 20 image is projected through a secondary suitable optical system 120 before contacting the film or wafer 30 and photo-resist 40 combination.

A particular object of the invention is to provide a means of restoring to normal corneas' whose surface has been damaged by trauma, failed LASIK, burns, and other mechanical disruptions, so that optical distortion, and/or reduction of transparency is reduced or eliminated. Diseases that impact the cornea include keratoconus, keratoglobus, pellucid marginal degeneration, and corneal dystrophies. The potential to either augment (as in keratoconus) or replace (as in corneal dystrophies such as Fuch's Endothelial Dystrophy) living corneal tissue is the object of this invention.

Still other objectives and possible applications of the invention will become evident to those knowledgeable in the related arts. The first of which is the ability to create a living corneal refractive lens to be implanted into existing stromal tissue.

### DETAILED DESCRIPTION OF THE INVENTION

The following example illustrates the practice of the invention in a preferred embodiment. The disclosed procedure offers a means of reconstructing corneal tissue, rebuilding stromal integrity, and corneal reshaping by laser surgery. The most widely practiced means of corneal repair has been corneal transplant. However, problems of tissue rejection, of immunosuppressive medication, gross refractive errors, and limited supplies of suitable donor tissue hamper transplants. While numerous experiments have been conducted in an effort to create laboratory-grown corneal tissue in vitro, the drawback of most of these methods is that they attempt to generate only one type of corneal cell structure, such as the epithelial or endothelial layers. Stromal creation in the laboratory has in the past been met with limited success since limited means have been found that successfully form the delicate collagen fibrils with micron sized diameters necessary for corneal transparency and diffusive permeability.

The disclosed invention teaches a method and means of using a modified form of photolithography similar to the art practiced in silicon chip fabrication to yield collagen fibrils in a regular lattice structure. The disclosed invention teaches how to control the density and orientation of a collagen fibril structure in order to achieve the desired diffusive and optical parameters compatible with natural tissue. The resulting polymer sheet can be trimmed and layered to the desired dimensions and can either be: inserted under a corneal cap during normal LASIK surgery to prevent ectasia, or can be placed as an corneal overlay to add structural reinforcement to the cornea in treating such disorders as keratoconus. Or, it can be used either intra-corneal or topically as a refractive correcting living contact lens which is absorbed and integrated into the native corneal stromal tissue.

The Corneal Stroma

The principal structural material of the cornea is collagen; its particular organization accounts for the transparency of the stroma. In the human cornea, collagen fibers have a uniform diameter and regular spacing between them. The fibers and the keratocytes between them are oriented in a parallel manner to form lamellae. The lamellae are superposed with others in a regular order, the collagen in each lamella being perpendicular to the adjacent lamellae. An important factor in transparency is the hydration of the proteoglycans; this determines the regular spacing of the collagen fibers and the distance between the fibers. The principal keratan sulfate proteoglycans are lumican, keratocan, and mimecan.

The galactosaminoglycans rich proteoglycans (chondroitin sulphate, dermatan sulphate, and keratan sulfate) that are expressed in the stroma have a high water affinity. Their water affinity is counterbalanced by the pump mechanisms in the endothelial cells. Proteoglycans also play a role binding the growth factors, and act as adhesive proteins. The differentiated connective tissue in the stroma contains 75% to 80% of water on a weight basis. Collagen, other proteins, and glycosaminoglycans of mucopolysaccharides constitute the major part of the remaining solids. Corneal fibrils are neatly organized and present the typical 64 to 66 nanometer periodicity of collagen. These collagen fibrils form the skeleton of the corneal stroma. The physicochemical properties of corneal collagen do not differ from those of tendon and skin collagen. Like collagen from these other sources, corneal collagen is rich in nitrogen, glycine, proline, and hydroxyproline. Mucopolysaccharides (MPS; glycosaminoglycans) represent 4% to 4.5% of the dry weight of the cornea. MPS are localized in the interfibrillar or interstitial space, probably attached to the collagen fibrils or to soluble proteins of the cornea. The MPS in the interstitial space play a role in corneal hydration through interactions with the electrolytes and water. Three major MPS fractions are found in the corneal stroma: keratin sulfate (50%), chondroitin (25%), and chondroitin sulfate (25%). The interstitial fibril structure must allow the MPS to flow freely, in concert with water and oxygen. All of this is necessary to promote corneal health, mechanical integrity, and optical clarity.

Creating A Replacement Corneal Stromal Collagen Structure

The disclosed invention offers a means of fabricating transparent stromal structures that can be implanted into a recipient cornea to augment or replace existing stromal tissue. The invention further permits creation of specialized collagen that integrates itself with the existing surrounding tissue to form a single, living, fully functional stroma. Additional benefits include the basis of in vitro creation of complete corneas and in vitro production of refractive correcting collagen based “contact lens” which can become a unit with the existing corneal tissue.

In order to realize a suitable stromal structure, fibrils of collagen, preferably Type I, must be created and layered to form the basis of a “mat” which exhibits the transparency and diffusion characteristics of healthy tissue. In the preferred embodiment, a photolithography process produces the effective polymer fibril matrix. It has been found that collagen for creating a suitable corneal mat as part of this invention can be derived from a variety of sources. In the preferred embodiment, synthetic collagen such as that manufactured by FibroGen of San Francisco, Calif. is dissolved by a suitable solvent, such as 1,1,1,3,3,3 hexaflouro-2-propanol (HFIPA), and deposited onto a suitable flat surface where the solvent is allowed to evaporate or is forcibly driven off into the vapor phase using applied heat or by exposure to partial pressure, forming a thin film which mimics the thickness of human corneal lamellar sheets. Next, the film is rinsed with water, and then dehydrated.

(It should be noted that an alternative source of suitable corneal collagen is the autologous transplantation of patient collagen derived from biopsy from a region or regions elsewhere in the body. One possibility is pluripotent stem cells from bone marrow. The marrow contains several cell populations, including mesenchymal stem cells that are capable of differentiating into adipogenic, osteogenic, chondrogenic, and myogenic cells. Since bone marrow procurement has obvious limitations, not the least of that is extreme discomfort for the patient during harvesting, an alternative source is desirable. One source found by Zuk et al., includes autologous stem cells from human adipose tissue obtained by suction-assisted lipectomy or liposuction. Grown in vitro, a fibroblast-like population of cells or a processed lipoaspirate, which differentiate into adipogenic cells that produce collagen.)

Regardless of the source, the collagen is prepared as described above to yield a thin film sheet ready for subsequent lithographic treatment similar to that utilized to produce silicon integrated circuits. Fabricating integrated circuits relies heavily on photolithography to define the shape and pattern of individual components. Photolithography is the process of transferring geometric shapes on a mask to the surface of a silicon wafer. During this process, a photoreactive polymer—a photoresist—is applied to the surface of a semiconductor wafer and cured through light exposure. Once a wafer's topography has been completed, the hardened resist must be removed. In the semiconductor case, the “light bulb” used is often a mercury arc lamp. The image comes from the reticle, and this is then projected through a very complex quartz glass lens system on to the wafer which has been coated (spun-on) with an ultra-thin layer of photoresist material. There are two types of photoresist: positive-and negative. Deep UV resists are solutions of an aromatic polymer and a photoacid generator in organic solvents. Positive photoresists (i-line and g-line) are comprised of a photoactive compound, a novolak resin, solvents, and certain other minor additives for enhanced functional performance. Negative resists are made of cyclized rubber, a sensitizer and organic solvents. High energy resists are solutions of polymers in organic solvents.

One of the most important steps in the photolithography process is mask alignment. A mask or “photomask” is a square glass plate with a patterned emulsion of metal film on one side. The mask is aligned with the wafer or collagen sheet, so that the pattern can be transferred onto the collagen polymer surface. There are three primary exposure methods: contact, proximity, and projection. The sheet is first treated with a film of light-sensitive “photo-resist”. Next, ultraviolet light is shone through the photomask and causes the photoresist to harden into a solid layer of tough acid-resistant polymer except, where shadows are cast by the opaque spots in the photomask. Etching the pattern transfer is accomplished by preferably an acid or solvent application process, (a solvent preferably being 1,1,1,3,3,3 hexaflouro-2-propanol (HFIPA)), which selectively removes unmasked portions of a layer. The portions of photoresist that remain in shadow are washed away, exposing the areas of the sheet where collagen remains, thus creating the desired pattern. The photoresist is stripped away using a suitable solvent not damaging to collagen.

Removal of the photoresist and any debris from the collagen film is preferably performed using a SCORR based device or Supercritical CO2 Resist Remover. Using such an instrument, photoresists, residues, and particles from the smallest features can be eliminated. A collagen film cross-section before SCORR cleaning is rough and jagged, whereas after SCORR cleaning the cross-section is smooth and free of minute particles. Because of its advanced cleaning process, SCORR is compatible with polymers such as create the corneal collagen scaffold.

Properly prepared collagen thin films are those that have been etched to create a regular lattice structure consisting of horizontal and vertical fibril elements approximately 65 nm in diameter and approximately 300 nm apart, are similar to a native stromal collagen lamellar sheet with regards to interfibrillar spacing and thickness. Multiple films are carefully layered until the desired thickness matches the lamellar layer to be duplicated. In some instances, however, it may be preferable to create a collagen matrix sheet thicker than native lamellar structure. Addition of glycerose is preferably used to effect polymer crosslinking, thus binding the collagen films together as a unit.

Collagen mats produced by this process can have diameters up to tens of millimeters and thickness of up to hundreds of microns, depending on the Ithographic pattern and the number of fabricated laminar sheets bound together and trimmed.

It will be obvious to those skilled in the art that other means may be employed that achieve the spirit of the invention. A few alternative photolithographic or ablation approaches are as follows:

X-Ray Lithography

In X-ray lithography, X-rays instead of UV (optical) rays are used to expose the photoresist. X-ray radiation has a shorter wavelength than UV radiation, and was developed as a technique to allow for additional reduction of the minimum dimensions of circuit elements. Thus far, however, the less expensive optical lithography techniques have been perfected so that elements with minimum dimensions approaching the size of those created using X-ray techniques (presently near 0.5 micrometer) can be produced. X-ray and optical lithography are both parallel processes in which the surface (or each die) of a photo-sensitive resist-coated wafer is exposed to radiation through a photomask.

E-Beam Lithography

Using e-beams, the pattern is written directly onto an electron-sensitive resist by serially scanning an E-beam across the collagen surface in the desired pattern. Very high pattern resolution can be achieved using E-beams. This technique is not commonly used, however, since E-beam exposure takes much longer than (parallel) optical and X-ray exposures. For example, parallel optical exposure of a 6 inch surface (with 0.75 micrometer resolution) typically takes 60 seconds, while E-beam exposure time can take up to an order of magnitude longer at 600 seconds. Thus, E-beam lithography is very expensive.

Laser Ablation

The use of laser ablation to remove unwanted collagen in creating a suitable tissue structure or scaffold is limited to such structures that have sufficient mechanical integrity to withstand the shock waves produced as a result of the rapid heating and vaporization of collagen.

Inserting the Replacement Collagen Tissue

After the fabricated fibril scaffold is produced, it is preferably laser trimmed into the desired diameter and thickness required for a given recipient. The recipient is preferably treated with pharmaceuticals used to treat glaucoma which reduce the intraocular pressure prior to the operative procedure. Employing epithelial debridement, epithelial placement to the side (such as in the LASIK procedure), or creation of a corneal flap (such as in LASIK) on the patient's target globe, the newly grown corneal cellular sheet is placed over the denuded corneal stroma. Orientation of an organized parallel fibril corneal sheet and the existing natural fibril structure, if required, may be accomplished by utilizing a polarized light and rotating the applied collagen sheet until a similar interference pattern is achieved. Glycerose is then applied to initiate collagen crosslinking between the corneal tissue and the fabricated collagen lamellar sheet, and thereby functions as an adhesive. If a flap has been created, additional glycerose is added before the flap is dropped, covering the repair. The use of glycerose assists in maintaining-corneal flap position during healing.

It should be noted that since adding collagen tissue may limit corneal flap suction when such a flap is replaced because overall corneal thickness will increase, glycerose-initiated crosslinking will secure the flap and added tissue in place, preventing a lost corneal cap. Further, glycerose treatment also minimizes or eliminates the possibility of corneal wrinkles or striae. An added benefit is that glycerose use actually increases the mechanical integrity of the cornea.

Experiments with rabbit eyes have shown that corneal transparency is lost when intraocular pressure is increased, but such is not the case with corneas similarly tested that have been previously treated with glycerose. This fact alone holds great promise in effecting interstitial bonding that we believe can keep keratoectasia (thinning of the cornea leading to distension and reduced vision) from occurring. Finally, the use of glycerose minimizes epithelial ingrowth.

After about three days, epithelial cells cover the repair site. The drugs employed to reduce the intraocular pressure are now discontinued and the healing tissue is allowed to stabilize over a period of three to six months. Corneal topographical data, wavefront measures of higher order aberrations, and other refractive measurements are then obtained and laser reshaping subsequently performed to effect final refractive correction.

### THE INVENTION IN SUMMATION

The corneal structure of the eye requires a permeable membrane to facilitate liquid and gaseous diffusion. Native tissue is composed of regular fibril structure or matrix composed of collagen which is not only diffusive, but which contains a fibril structure favorable to the transmission of visible light.

The disclosed invention utilizes lithographic means to define and produce a desired pattern in a given polymer suited for ophthalmic use, in this case, preferably collagen. The lithographic process may be performed in ambient atmosphere, an inert atmosphere, or a vacuum depending on the amount of vapor produced by the process or to minimize potentially undesirable target-gas interactions. Energy, preferably ultraviolet (UV) light, is passed through a suitable mask which possesses the desired polymer pattern. The target is covered with a layer of suitable photoresist material. The light is suitably focused on the target, which is preferably a sheet of dehydrated collagen, and hardend the photoresist only in the areas not obscured by the mask pattern. Etching the pattern transfer is accomplished by application of a suiable acid or solvent process, which selectively removes unmasked portions of a layer. The portions of photoresist that remain in shadow are washed away with a suitable solvent, exposing the areas of the collagen sheet with the desired pattern. The photoresist is stripped away with a suitable solvent.

It should be noted that a lithographic mask may be eliminated through the use of controlled application of laser, ion beam, electron beam, or molecular beam bombardment of the collagen polymer target. Ordered matrices or other patterns can be produced by the ablation or removal of collagen in those areas where such a beam is concentrated.

I claim:

1. A method of producing microstrands matrices of a polymer, comprising:
forming a sheet of collagen, covering said sheet with photoresist, exposing said sheet to radiation passed through a mask,
where said light hardens said photoresist, stripping away areas of photoresist not so hardened, and removing photoresist leaving behind desired pattern.

2. The method of claim 1, where said polymer is collagen

3. The method in claim 1 where said radiation is visible light

4. The method in claim 1 where said radiation is ultraviolet
